(19) United States
(12) Patent Application Publication
(10) Pub. No.: US 2003/0209741 A1
(43) Pub. Date: Nov. 13, 2003

(54) Insulated gate semiconductor device

(76) Inventors: Wataru Saitoh, Kawasaki-shi (JP); Ichiro Omura, Yokohama-shi (JP); Satoshi Aida, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/183,457

(22) Filed: Jun. 28, 2002

(30) Foreign Application Priority Data
Apr. 26, 2002 (JP) 2002-127334

(51) Int. Cl. H01L 29/74

(52) U.S. Cl. 257/288

(57) ABSTRACT

An insulated gate semiconductor device includes a plurality of second semiconductor layers of a second conductivity type selectively formed in a surface area of a first semiconductor layer of a first conductivity type. At least one third semiconductor layer of the first conductivity type is formed in a surface area of each of the second semiconductor layers. A fourth semiconductor layer is formed on the bottom of the first semiconductor layer. At least one fifth semiconductor layer of the second conductivity type is provided in the first semiconductor layer and connected to at least one of the plurality of second semiconductor layers. The fifth semiconductor layer has impurity concentration that is lower than that of the second semiconductor layers.

### CROSS-REFERENCE TO RELATED APPLICATIONS

This application is based upon and claims the benefit of priority from the prior Japanese Patent Application No. 2002-127334, filed Apr. 26, 2002, the entire contents of which are incorporated herein by reference.

### BACKGROUND OF THE INVENTION

1. Field of the Invention

The present invention relates to an insulated gate semiconductor device used for power control. More specifically, the invention relates to a MOS gate device such as a switching power MOSFET (metal oxide semiconductor field effect transistor) and an IGBT (insulated gate bipolar transistor).

2. Description of the Related Art

To increase in switching frequency is effective in miniaturizing a power supply circuit such as a switching power supply. In other words, downsizing a passive element such as an inductance and a capacitor in a power supply circuit is effective. However, as the switching frequency heightens, a switching loss of switching elements such as a MOSFET and an IGBT increases. The increase in switching loss lowers the efficiency of a power supply. A decrease in switching loss due to a speedup of switching elements is therefore essential to miniaturization of a power supply circuit.

In MOS gate elements, such as a MOSFET and an IGBT, currently used as switching elements, a gate length is shortened and thus the opposing area of gate and drain electrodes is decreased. Consequently, the MOS gate elements can be increased in speed by reducing gate-to-drain capacitance.

If, however, the gate-to-drain capacitance is reduced to speed up the MOS gate elements, resonance occurs between parasitic inductance and switching element capacitance contained in wiring. The resonance becomes a factor in causing high-frequency noise (switching noise) at the time of switching. To suppress the switching noise, soft switching has to be performed or a filter circuit has to be provided or a gate drive circuit has to be devised. The suppression of switching noise increases costs.

As described above, conventionally, high-speed switching can be achieved by reducing gate-to-drain capacitance. However, switching noise should be suppressed and thus soft switching should be performed or an external circuit such as a filter circuit should be employed.

### BRIEF SUMMARY OF THE INVENTION

An insulated gate semiconductor device according to an embodiment of the present invention comprises:

a first semiconductor layer of a first conductivity type;

a plurality of second semiconductor layers of a second conductivity type selectively formed in a surface area of the first semiconductor layer;

at least one third semiconductor layer of the first conductivity type formed in a surface area of each of the second semiconductor layers;

a plurality of first main electrodes connected to the second semiconductor layers and the third semiconductor layer, respectively;

a fourth semiconductor layer formed on a bottom of the first semiconductor layer;

a second main electrode connected to the fourth semiconductor layer;

a control electrode formed on a surface of each of the second semiconductor layers, the third semiconductor layer, and the first semiconductor layer with a gate insulation film interposed therebetween; and

at least one fifth semiconductor layer of the second conductivity type provided in the first semiconductor layer and connected to at least one of the plurality of second semiconductor layers, the fifth semiconductor layer having impurity concentration that is lower than that of the second semiconductor layers.

### BRIEF DESCRIPTION OF THE SEVERAL VIEWS OF THE DRAWING

FIG. 1 is a partially cutaway perspective view showing a structure of a vertical power MOSFET according to a first embodiment of the present invention.

FIG. 2 is a graph showing the dependency of gate-to-drain capacitance upon source-to-drain voltage in the MOSFET shown in FIG. 1 and that in a prior art MOSFET to compare them with each other.

FIG. 3 is a graph showing a drain voltage waveform and a drain current waveform generated when the MOSFET shown in FIG. 1 turns off and those generated when a prior art MOSFET turns off to compare them with each other.

FIG. 4 is a partially cutaway perspective view showing another structure of a vertical power MOSFET according to the first embodiment of the present invention.

FIG. 5 is a partially cutaway perspective view showing still another structure of a vertical power MOSFET according to the first embodiment of the present invention.

FIG. 6 is a graph showing a turnoff waveform of the MOSFET according to the first embodiment of the present invention and that of the prior art MOSFET to compare them with each other.

FIG. 7 is a graph showing variations in turnoff loss caused when a gate-underlying p-type layer varies in area in the MOSFET according to the first embodiment of the present invention.

FIG. 8 is a graph showing variations in turnoff loss caused when a gate-underlying p-type layer varies in net dose in the MOSFET according to the first embodiment of the present invention.

FIG. 9 is a graph showing a relationship between the distance between p-type base layers and the maximum net dose of the gate-underlying p-type layer in the MOSFET according to the first embodiment of the present invention.

FIG. 10 is a cross-sectional view showing a structure of a main part of a power MOSFET according to a second embodiment of the present invention.

FIG. 11 is a cross-sectional view showing a structure of a main part of a power MOSFET according to a third embodiment of the present invention.

FIG. 12 is a cross-sectional view showing another structure of the main part of a power MOSFET according to the third embodiment of the present invention.

FIG. 13 is a cross-sectional view showing a structure of a main part of a power MOSFET according to a fourth embodiment of the present invention.

FIG. 14 is a cross-sectional view showing another structure of the main part of a power MOSFET according to the fourth embodiment of the present invention.

FIG. 15 is a partially cutaway perspective view showing a structure of a power MOSFET according to a fifth embodiment of the present invention.

FIG. 16 is a partially cutaway perspective view showing a structure of a power MOSFET according to a sixth embodiment of the present invention.

FIG. 17 is a partially cutaway perspective view showing another structure of the power MOSFET according to the sixth embodiment of the present invention.

FIG. 18 is a partially cutaway perspective view showing still another structure of the power MOSFET according to the sixth embodiment of the present invention.

FIG. 19 is a plan view showing an example of layout of gate-underlying p-type layers in the power MOSFET according to the sixth embodiment of the present invention.

FIG. 20 is a plan view showing another example of layout of gate-underlying p-type layers in the power MOSFET according to the sixth embodiment of the present invention.

FIG. 21 is a plan view showing still another example of layout of gate-underlying p-type layers in the power MOSFET according to the sixth embodiment of the present invention.

FIG. 22 is a cross-sectional view showing a structure of a main part of an IGBT according to a seventh embodiment of the present invention.

FIG. 23 is a cross-sectional view showing another structure of the main part of the IGBT according to the seventh embodiment of the present invention.

FIG. 24 is a cross-sectional view showing still another structure of the main part of the IGBT according to the seventh embodiment of the present invention.

FIG. 25 is a cross-sectional view showing a structure of a main part of a power MOSFET according to an eighth embodiment of the present invention.

FIG. 26 is a cross-sectional view showing a structure of a main part of an IGBT according to an eighth embodiment of the present invention.

FIG. 27 is a cross-sectional view showing a structure of a main part of a power MOSFET according to a ninth embodiment of the present invention.

FIG. 28 is a cross-sectional view showing another structure of the main part of the power MOSFET according to the ninth embodiment of the present invention.

### DETAILED DESCRIPTION OF THE INVENTION

Embodiments of the present invention will now be described with reference to the accompanying drawings. In each of the embodiments, a first conductivity type is an n type and a second conductivity type is a p type.

(First Embodiment)

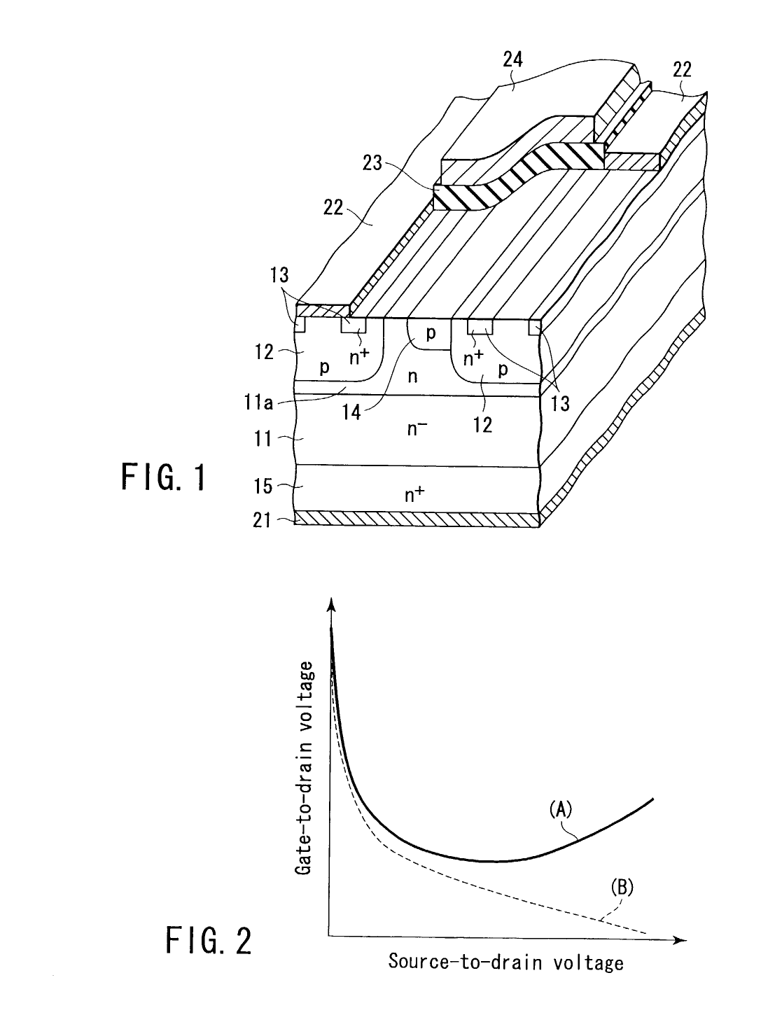

FIG. 1 shows a structure of a vertical power MOSFET according to a first embodiment of the present intention.

Referring to FIG. 1, an n-type low resistance layer 11a is formed by diffusion on one surface (top) of an n⁻-type drift layer 11 serving as a first semiconductor layer. A plurality of p-type base layers 12 are selectively formed by diffusion as second semiconductor layers in a surface area of the layer 11a. The p-type base layers 12 are each shaped like a strip in a first direction perpendicular to the front of the MOSFET. A plurality of n⁺-type source layers 13 are selectively formed by diffusion as third semiconductor layers in a surface area of each of the p-type base layers 12.

A p-type layer 14 is selectively formed by diffusion as a fifth semiconductor layer in a surface area of the n-type low resistance layer 11a and between adjacent two p-type base layers 12. The p-type layer 14 is shaped like a strip in the first direction along the p-type base layers 12 and contacts one of adjacent p-type base layers 12. The p-type layer 14 has impurity concentration that is lower than that of the p-type base layers 12.

An n⁺-type drain layer 15 is formed as a fourth semiconductor layer on the other surface (bottom) of the n⁻-type drift layer 11. A drain electrode 21 serving as a second main electrode contacts the entire surface of the layer 15.

A source electrode 22, which includes part of the n⁺-type source layers 13, is formed as a first main electrode on each of the p-type base layers 12. The source electrodes 22 are each shaped like a strip in the first direction. A planar gate electrode 24 is formed as a control electrode between adjacent source electrodes 22 through a gate insulation film 23 (e.g., a silicon oxide film). In other words, the gate electrode 24 is formed within a region extending from the n⁺-type source layer 13 in one p-type base layer 12 to that in another p-type base layer 12 via the n-type low resistance layer 11a and p-type layer 14. The gate insulation film 23 has a thickness of about 0.1 μm.

For example, a substrate that is obtained by forming an n⁻-type layer on a low resistance silicon substrate by epitaxial growth is used to form the above-described n⁻-type drift layer 11 and n⁺-type drain layer 15. Another substrate that is obtained by forming an n⁺-type layer on a silicon substrate by diffusion can be used.

The p-type layer 14 is formed in that surface area of the n-type low resistance layer 11a that is formed under the gate electrode 24 between the p-type base layers 12 (the layer 14 is also referred to as a gate-underlying p-type layer hereinafter). The p-type layer 14 has impurity concentration that is lower than that of the p-type base layers 12. The layer 14 is depleted when a high voltage is applied. High-speed and low-noise switching characteristics can thus be achieved in the MOSFET according to the first embodiment. More specifically, the MOSFET achieves high-speed and low-noise switching characteristics using characteristics that gate-to-drain capacitance increases in response to a drain voltage.

FIG. 2 shows the dependency of gate-to-drain capacitance upon source-to-drain voltage in the MOSFET according to the first embodiment and that in a prior art MOSFET (not shown) to compare them with each other.

In the prior art MOSFET indicated by a broken line (B), the gate-to-drain capacitance continues to decrease in proportion to the source-to-drain voltage.

In contrast, in the MOSFET of the present invention indicated by a solid line (A), the gate-to-drain capacitance increases as the source-to-drain voltage becomes high. In other words, the gate-to-drain capacitance gradually decreases if the source-to-drain voltage is low. As the source-to-drain voltage heightens, the gate-to-drain capacitance increases. The reason is as follows. The increase in source-to-drain voltage (high drain voltage) depletes the gate-underlying p-type layer 14 and thus the apparent opposing area of the gate electrode 24 and drain electrode 21 increases as the apparent gate length does.

The smaller the gate-to-drain capacitance, the higher the switching speed of the MOSFET. If, however, the capacitance is small when the MOSFET completely turns off, a spike voltage increases. It is desirable that the capacitance should be small when the MOSFET starts to turn off or when the drain voltage is low and it should be large when the MOSFET finishes turning off or when the drain voltage is high.

In the prior art MOSFET (B), the narrower the interval between p-type base layers, the smaller the opposing area of the gate and drain electrodes. In other words, the gate-to-drain capacitance decreases. If a drain voltage is applied, a depletion layer extends from the p-type base layers. The gate-to-drain capacitance decreases more and more. A gate driving circuit is therefore required to achieve high-speed, low-noise switching. Complicated control such as a gradual decrease in gate current is also required.

The MOSFET according to the first embodiment makes the use of characteristics that the gate-to-drain capacitance increases in response to the drain voltage. In other words, when the MOSFET starts to turn off, the gate-underlying p-type layer 14 is not depleted by a low drain voltage and the interval between p-type base layers 12 is narrowed. Thus, the opposing area of the gate electrode 24 and drain electrode 21 decreases and so does the gate-to-drain capacitance, thereby securing high-speed switching characteristics. On the other hand, when the MOSFET finishes turning off by a high drain voltage, the layer 14 is depleted and the apparent interval between p-type base layers 12 is broadened. Thus, the opposing area of the gate electrode 24 and drain electrode 21 increases and so does the gate-to-drain capacitance, thereby preventing the drain voltage from spiking to reduce switching noise. Consequently, high-speed, low-noise switching characteristics can be achieved without any external circuit or complicated control.

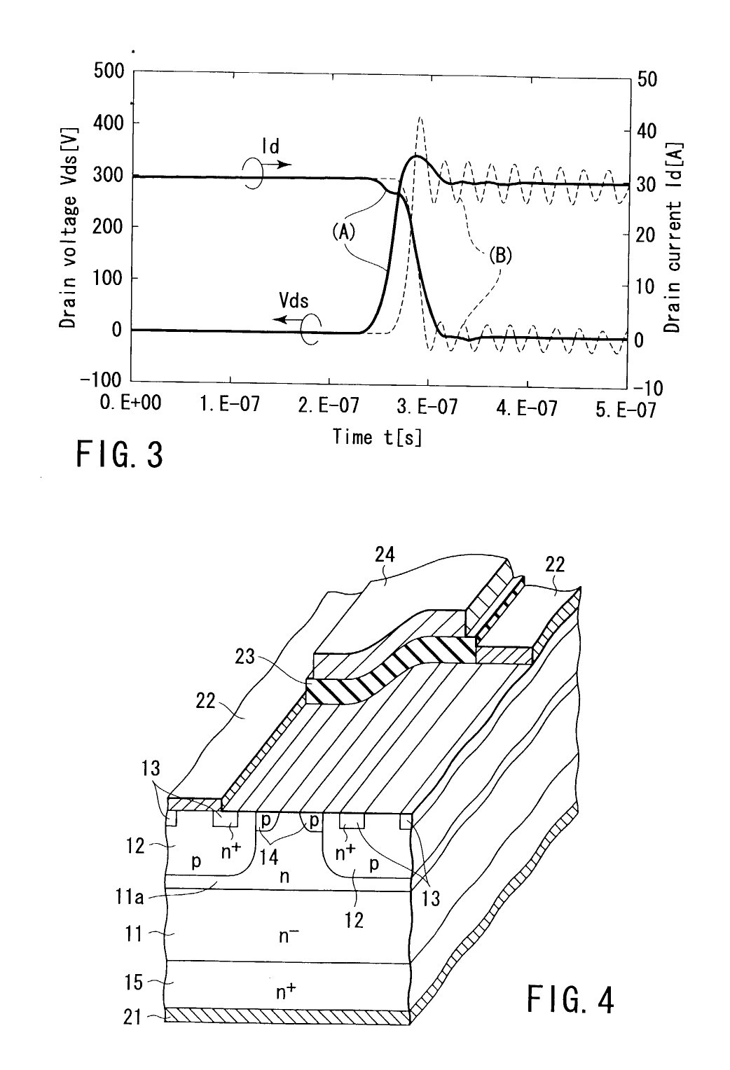

FIG. 3 shows a drain voltage (Vds) waveform and a drain current (Id) waveform generated when the MOSFET shown in FIG. 1 turns off and those generated when a prior art MOSFET turns off to compare them with each other.

In the prior art MOSFET indicated by a broken line (B) in FIG. 3, the switching speed is increased by shortening the gate length as has been described above. The spike voltage (drain voltage Vds) generated when the MOSFET turns off increases in proportion to the switching speed as indicated by a broken line in FIG. 3. The drain voltage Vds greatly varies thereafter and is not stabilized easily.

In contrast, the MOSFET of the present invention indicated by a solid line (A) decreases in the gate-to-drain capacitance when a low drain voltage is applied and increases in the gate-to-drain capacitance when a high drain voltage is applied. The switching speed remains high and the spike voltage lowers by more than half that of the prior art MOSFET as indicated by the broken line in FIG. 3. The drain voltage Vds is prevented from varying.

In the MOSFET shown in FIG. 1, the gate-underlying p-type layer 14 is formed on one of adjacent two p-type base layers 12. The present invention is not limited to this formation. For example, a gate-underlying p-type layer 14 can be formed on each of adjacent two p-type base layers 12, as shown in FIG. 4.

The gate-underlying p-type layers 14 are not necessarily formed more shallowly than the p-type base layers 12. The layers 14 can be depleted at a high drain voltage in terms of operation. Therefore, the layers 14 can be formed to the same depth as that of the p-type base layers 12 or they can be done more deeply than the base layers 12. If, however, the layers 14 are formed shallowly, the effective opposing area of the gate electrode 24 and drain electrode 21 greatly increases when the layers 14 are completely depleted. Thus, the gate-to-drain capacitance varies with an increase in drain voltage and a great advantage of low-noise switching can be obtained. It is thus desirable to form the gate-underlying p-type layers 14 more shallowly than the p-type base layers 12.

In the MOSFET depicted in FIG. 1, the n-type low resistance layer 11a is provided in order to reduce the resistance between adjacent p-type base layers 12. In other words, the layer 11a is formed more deeply than the p-type base layers 12. Resistance can thus be prevented from expanding to the broad n⁻-type drift layer 11 from a narrow JFET (junction FET) region interposed between the p-type base layers 12. The n-type low resistance layer 11a can be formed more shallowly than the p-type base layers 12 in order to lower on-resistance.

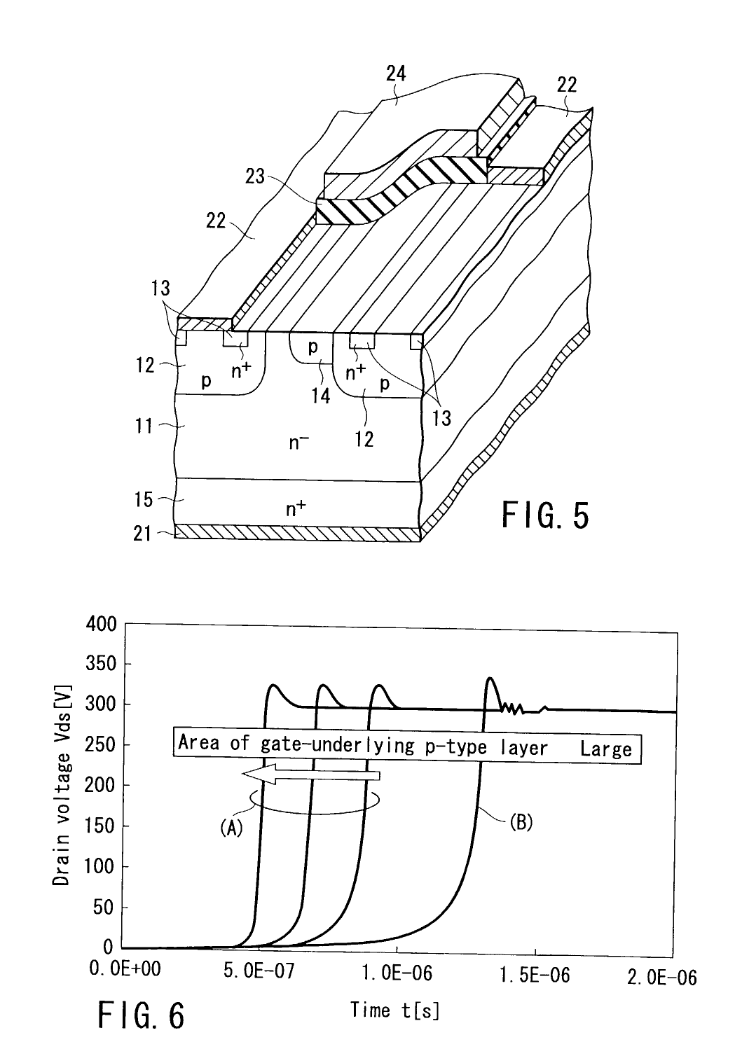

The n-type low resistance layer 11a does not affect high-speed, low-noise switching characteristics. The formation of an n-type low resistance layer can thus be omitted as shown in FIG. 5. The same is true of the MOSFET shown in FIG. 4.

Paying attention to on-resistance as well as high-speed switching, gate capacitance indicative of the high-speed switching is usually proportional to the area and the on-resistance is inversely proportional to the area. There is a trade-off relationship between high-speed switching and low on-resistance. In the MOSFET of the first embodiment, however, its switching speed can be increased simply by slightly increasing a channel resistance and the resistance of the JFET region. The trade-off relationship between high-speed switching and low on-resistance is therefore improved. The on-resistance can easily be made lower without changing the switching speed.

The rated voltage (withstanding voltage) of a switching element is usually 1.5 times to 3 times as high as the power supply voltage. It is thus desirable that the gate-to-drain capacitance be increased with respect to a voltage that is almost equal to the power supply voltage. In other words, it is desirable that the switching element have a characteristic that its gate-to-drain capacitance starts to increase at a voltage that is one-third to two-thirds of the rated voltage.

If the gate-underlying p-type layer 14 is completely depleted, the opposing area of the gate and drain electrodes 24 and 21 greatly increases and so does the gate-to-drain capacitance. It is thus desirable that the gate-underlying p-type layer 14 be completely depleted at a voltage that is one-third to two-thirds of the rated voltage.

The gate-to-drain capacitance increases if the gate-underlying p-type layer 14 is completely depleted (see FIG. 2). However, when the gate-to-drain capacitance does not increase or its decrease stops to a given amount or its decrease is minimized, the capacitance at the time of turnoff becomes larger than that in the prior art MOSFET. Switching noise is therefore suppressed and the gate-underlying p-type layer 14 is not depleted completely but can be done partially.

FIG. 6 shows a turnoff waveform of the MOSFET (A) according to the first embodiment of the present invention and that of the prior art MOSFET (B) to compare them with each other.

When a low drain voltage is applied, the p-type layer 14 decreases the gate-to-drain capacitance; therefore, switching speed is increased. When a high drain voltage is applied, the p-type layer 14 is depleted. Thus, the apparent gate length increases and so does the gate-to-drain capacitance. The jumping voltage can thus be suppressed.

As is apparent from FIG. 6, the switching speed becomes high with increase in the area of the p-type layer 14 to be depleted between p-type base layers 12 under the gate electrode 24.

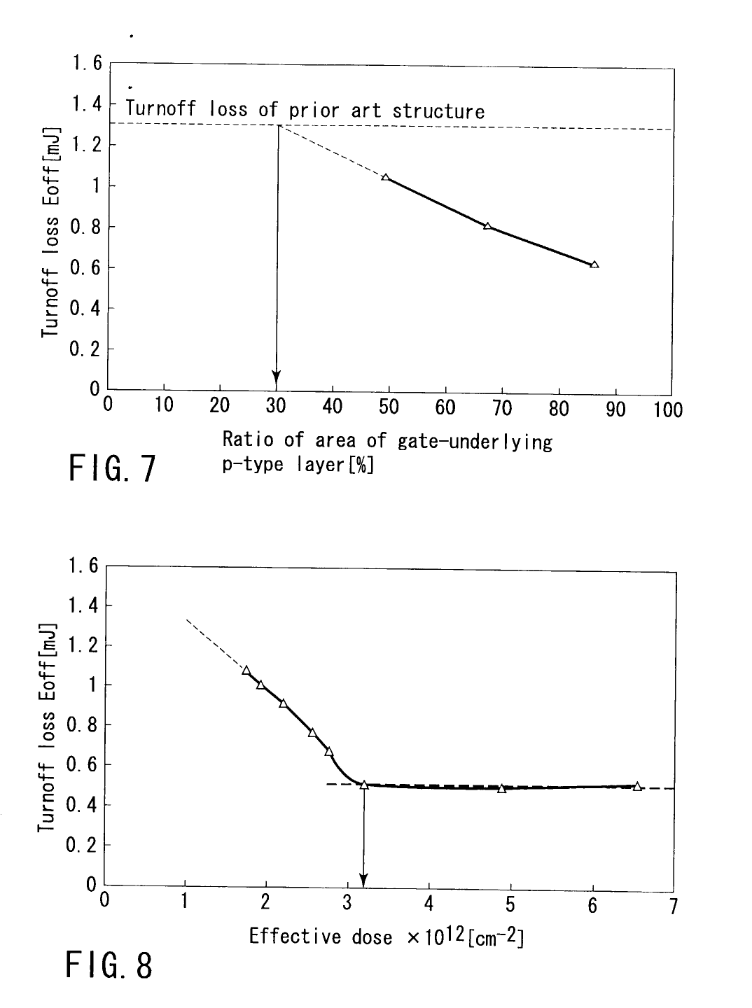

FIG. 7 is a graph showing variations in turnoff loss (Eoff) caused when the area of the gate-underlying p-type layer 14 varies in the MOSFET according to the first embodiment. In this graph, the horizontal axis indicates the ratio of the p-type layer 14 to be depleted to a region between p-type base layers 12 under the gate electrode 24, while the vertical axis indicates a turnoff loss in an inductive load.

As shown in FIG. 7, when the ratio is 30% or more, the MOSFET becomes effective in high-speed switching and it is estimated that the turnoff loss becomes smaller than that (1.35 mJ) of the prior art MOSFET. It is thus desirable that the ratio be larger than 30%.

FIG. 8 shows variations in turnoff loss caused when the gate-underlying p-type layer 14 varies in net dose (effective dose) in the MOSFET according to the first embodiment.

The net dose represents not the amount of impurity to be actually ion-implanted but the amount of impurity that corresponds to the number of carriers existing in the p-type layer 14 and that is obtained by subtracting the amount of n-type impurity existing between p-type base layers 12 from the amount of p-type impurity.

If the net dose is small, the p-type layer 14 will be completely depleted at a low voltage; therefore, the degree of effectiveness of high-speed switching is low. When the net dose exceeds a given value, the p-type layer 14 is not depleted when a high voltage is applied and the capacitance does not increase. In this case, the switching speed can be increased, but the turnoff loss is fixed, thereby increasing switching noise as in the normal high-speed switching. It is thus desirable that the net dose of the p-type layer 14 be set at 3.2×10¹² cm⁻² or smaller.

Assume that dopant of the n-type low resistance layer 11a is phosphorus (P) and that of the gate-underlying p-type layer 14 is boron (B) in order to actually manufacture a MOSFET. The layers 11a and 14 can be formed by diffusing the dopants at the same time from the viewpoint of a difference in diffusion constant.

Since the n-type low resistance layer 11a and p-type layer 14 of high concentrations overlap each other, the net dose and the amount of impurity to be actually ion-implanted differ from each other. The amount of impurity to be ion-implanted has only to be controlled such that the net dose has the optimum value as shown in FIG. 8.

FIG. 9 shows a relationship between the distance Lj between adjacent p-type base layers 12 and the maximum net dose Np of the gate-underlying p-type layer 14 that is effective in low noise in the MOSFET according to the first embodiment. In FIG. 9, the depth Xj of the p-type base layers 12 is 4 μm.

The maximum net dose Np is an upper limit at which the gate-underlying p-type layer 14 is depleted when a high voltage is applied. If the dose increases further, neither the layer 14 is depleted nor the gate capacitance is increased. Noise therefore increases. It is thus desirable that the net dose of the gate-underlying p-type layer 14 be not higher than the maximum net dose Np.

As shown in FIG. 9, the maximum net dose Np is almost proportionate to the distance Lj between p-type base layers 12. It is thus desirable that the ratio (Np/Lj) of the maximum net dose Np to the distance Lj between p-type base layers 12 be 2×10¹⁵ cm⁻³ or smaller.

If the p-type base layers 12 deepen, it is difficult to apply a drain voltage to the gate-underlying p-type layer 14 and thus difficult to deplete the layer 14. Therefore, the maximum net dose Np is inversely proportionate to the depth Xj of the p-type base layers 12.

If the depth Xj is 4 μm as shown in FIG. 9, it is desirable that the ratio (Np/(Lj·Xj)) of the maximum net dose Np and the product of the depth Xj of the base layers 12 and distance Lj between them be 5×10¹⁸ cm⁻⁴ or smaller.

(Second Embodiment)

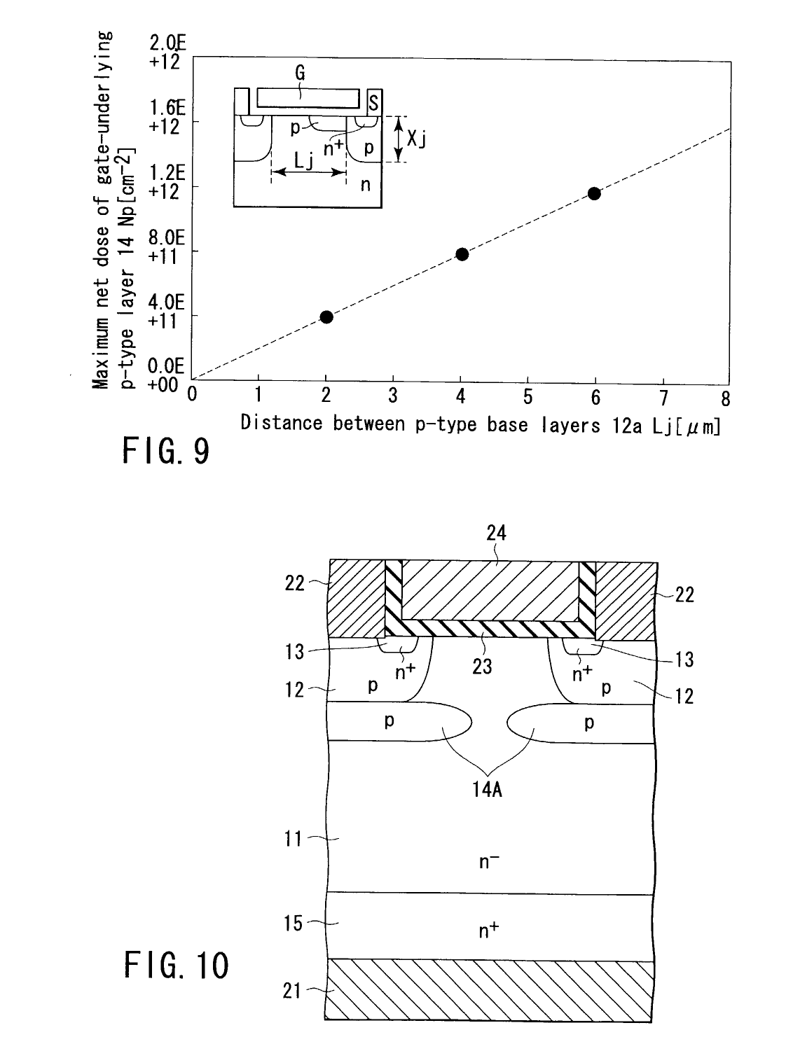

FIG. 10 shows an example of a structure of a power MOSFET according to a second embodiment of the present invention. In FIG. 10, the same components as those of the MOSFET shown in FIG. 1 are denoted by the same reference numerals and their detailed descriptions are omitted. Only the components different from those in FIG. 1 will be described. The formation of an n-type low resistance layer is omitted from FIG. 10.

Referring to FIG. 10, p-type layers 14A serving as fifth semiconductor layers are buried in an n⁻-type drift layer 11. The p-type layers 14A are arranged below their respective p-type base layers 12 adjacent to each other. The p-type layers 14A are connected to the p-type base layers 12, respectively. Each of the p-type layers 14A is formed like a strip in a first direction along the p-type base layers 12. The p-type layers 14A each have impurity concentration that is lower than that of each of the p-type base layers 12.

As in the MOSFET shown in FIG. 1, the p-type layers 14A are depleted by applying a high drain voltage. As the opposing area of a gate electrode 24 and a drain electrode 21 increases, the gate-to-drain capacitance increases. High-speed, low-noise switching characteristics can thus be achieved.

If the p-type layers 14A are formed between the gate electrode 24 and drain electrode 21, substantially the same advantages as those of the first embodiment can be obtained. Consequently, the p-type layers depleted by a high drain voltage are not always formed on the surface of an n⁻-type drift layer (or an n-type low resistance layer).

The manufacturing process of the MOSFET according to the second embodiment is slightly more complicated than that of the MOSFET according to the first embodiment. In other words, the manufacturing process is complicated by the step of forming the p-type layers 14A in the n⁻-type drift layer 11. However, as an electric field concentrates near the bottoms of the p-type base layers 12 when a high voltage is applied, the breakdown voltage becomes high than that in the MOSFET shown in FIG. 1.

(Third Embodiment)

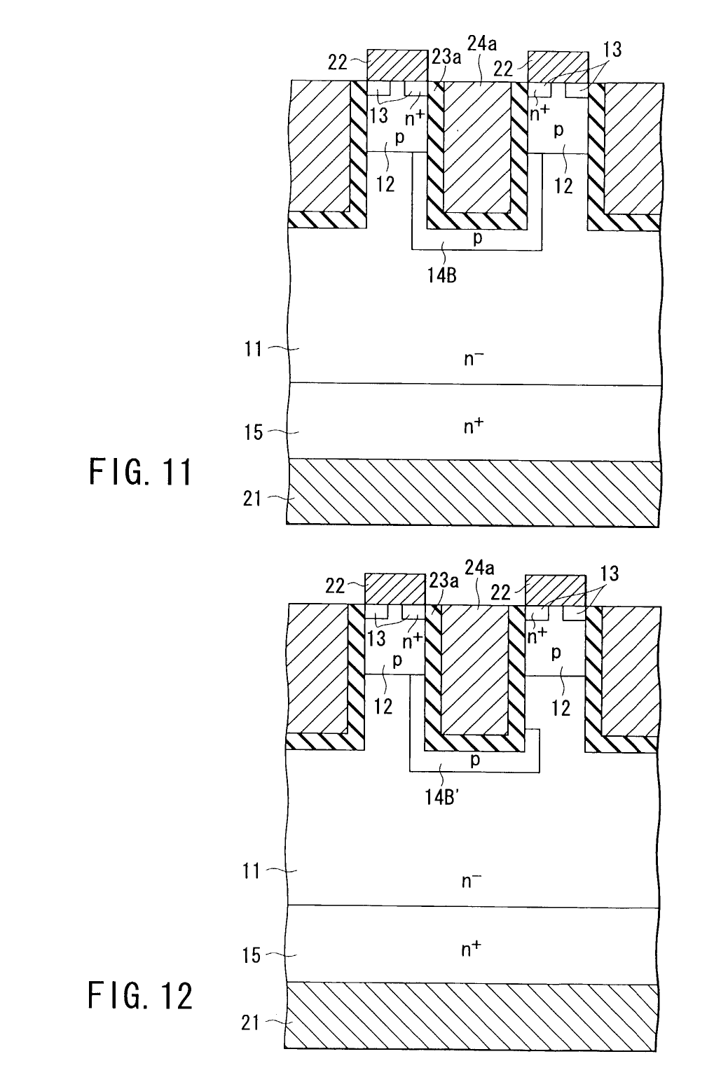

FIG. 11 shows an example of a structure of a power MOSFET according to a third embodiment of the present invention. In FIG. 11, the same components as those of the MOSFET shown in FIG. 1 are denoted by the same reference numerals and their detailed descriptions are omitted. Only the components different from those in FIG. 1 will be described. The formation of an n-type low resistance layer is omitted from FIG. 11.

Referring to FIG. 11, a gate electrode 24a serving as a control electrode is buried in a surface area of an n⁻-type drift layer 11 with a gate insulation film 23a interposed therebetween. In other words, a gate electrode 24a having a trench structure (trench gate) is formed like a strip between adjacent two p-type base layers 12. A p-type layer 14B serving as a fifth semiconductor layer is formed around the trench gate 24a. The p-type layer 14B is connected to one of the p-type base layers 12 and has impurity concentration that is lower than that of the p-type base layers 12.

In the second embodiment, the p-type layer 14B is not depleted when a low drain voltage is applied. The gate-to-drain capacitance is therefore decreased to allow a high-speed switching operation to be performed. The p-type layer 14B is depleted when a high drain voltage is applied. Thus, the apparent gate area increases, as does the gate-to-drain capacitance, with the result that noise is reduced. Substantially the same advantages as those of the MOSFET having a planar gate electrode shown in FIG. 1, that is, high-speed, low-noise switching characteristics can be obtained.

In the MOSFET according to the second embodiment, the number of trench gates 24a can be varied and so can be the ratio of the area of the p-type layer 14B to that of the trench gate 24a. It is thus possible to obtain the same advantages as those of the MOSFET shown in FIG. 1 in which the area ratio of the p-type layer is varied.

For example, a p-type layer 14B′ can be formed so as to surround one sidewall of the trench gate 24a and the bottom thereof as shown in FIG. 12. In other words, a p-type layer 14B′ can be formed on the trench gate 24a excluding part of the sidewall thereof. In this case, a channel through which no current flows completely need not be formed; therefore, low on-resistance can be achieved.

(Fourth Embodiment)

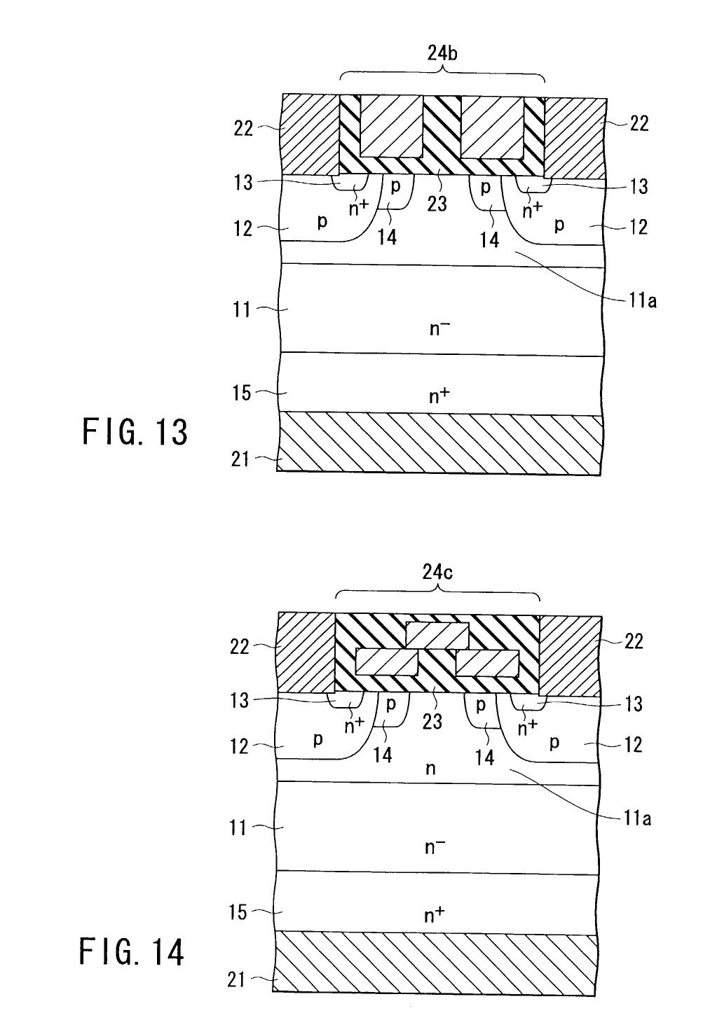

FIG. 13 shows an example of a structure of a power MOSFET according to a fourth embodiment of the present invention. In FIG. 13, the same components as those of the MOSFET shown in FIG. 1 are denoted by the same reference numerals and their detailed descriptions are omitted. Only the components different from those iii FIG. 1 will be described. The MOSFET shown in FIG. 13 includes an n-type low resistance layer.

Referring to FIG. 13, a gate electrode 24b serving as a control electrode has a split gate structure. Two gate-underlying p-type layers 14 each serving as a fifth semiconductor layer are formed in a surface area of an n-type low resistance layer 11a. The two gate-underlying p-type layers 14 are connected to adjacent p-type base layers 12, respectively and have impurity concentration that is lower than that of the p-type base layers 12.

If a gate electrode has a split gate structure, the gate capacitance decreases to increase the speed of switching. High-speed switching characteristics can thus be achieved when the gate-underlying p-type layers 14 are formed.

As a process of manufacturing a MOSFET according to the fourth embodiment, a gate electrode 24b can be formed (split) after a gate-underlying p-type layer 14 is formed or after a gate-underlying p-type layer 14 is formed on the entire surface of an n-type low resistance layer 11a. Using the gate electrode 24b as a mask, the n-type low resistance layer 11a can be formed (the p-type layer 14 can be split).

The gate structure of the gate electrode 24b is not limited to the above split gate structure. For example, a gate electrode (control electrode) 24c having a terrace gate structure can be used as shown in FIG. 14. In this case, too, substantially the same advantages as those in the split gate structure can be obtained.

(Fifth Embodiment)

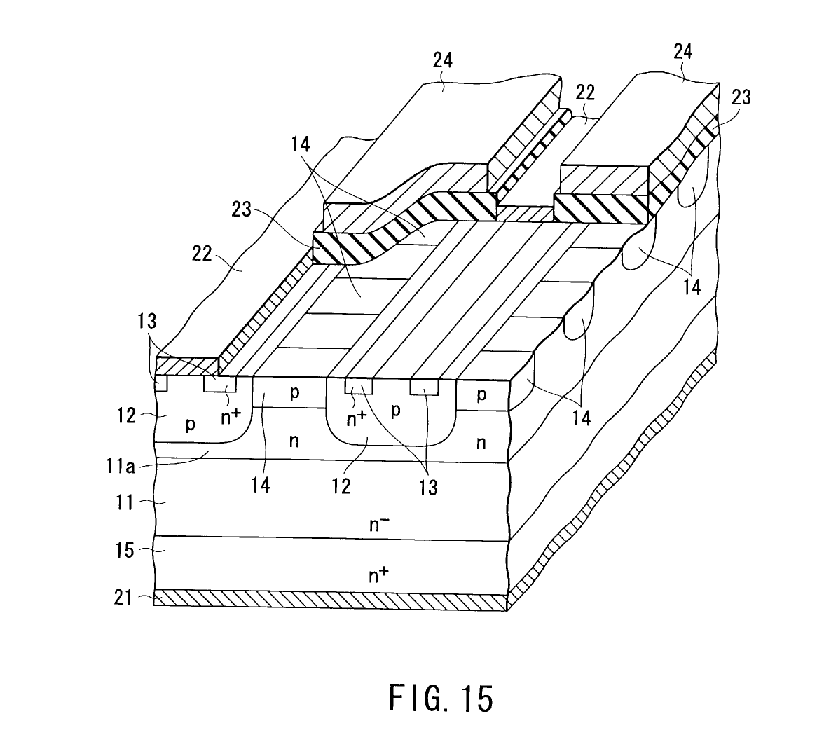

FIG. 15 shows an example of a structure of a power MOSFET according to a fifth embodiment of the present invention. In FIG. 15, the same components as those of the MOSFET shown in FIG. 1 are denoted by the same reference numerals and their detailed descriptions are omitted. Only the components different from those in FIG. 1 will be described. The MOSFET shown in FIG. 15 includes an n-type low resistance layer.

Referring to FIG. 15, a plurality of p-type base layers 12 serving as second semiconductor layers are each formed like a strip in a first direction perpendicular to the front of the MOSFET. A plurality of gate-underlying p-type layers 14 serving as fifth semiconductor layers are each formed like a strip in a second direction perpendicular to the p-type base layers 12.

Not only substantially the same advantages as those of the MOSFET shown in FIG. 1 can be obtained but other advantages can be expected from the MOSFET shown in FIG. 15. For example, a p-type layer 14 to be depleted can be formed without any influence of misalignment.

(Sixth Embodiment)

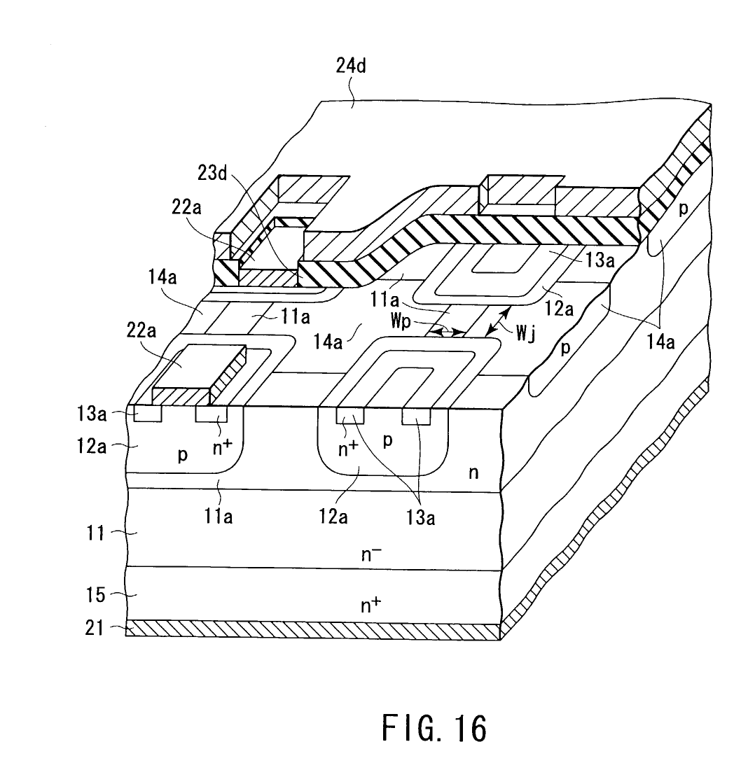

FIG. 16 shows an example of a structure of a power MOSFET according to a sixth embodiment of the present invention. In FIG. 16, the same components as those of the MOSFET shown in FIG. 1 are denoted by the same reference numerals and their detailed descriptions are omitted. Only the components different from those in FIG. 1 will be described. The MOSFET shown in FIG. 16 includes an n-type low resistance layer.

Referring to FIG. 16, a plurality of p-type base layers 12a serving as second semiconductor layers are arranged in a latticed manner (or staggered manner) in a surface area of an n-type low resistance layer 11a. A plurality of gate-underlying p-type layers 14a serving as fifth semiconductor layers are each formed like a rectangle between adjacent four p-type base layers 12a.

A plurality of n⁺-type source layers 13a serving as third semiconductor layers are each formed like a ring in the surface area of each of the p-type base layers 12a. Rectangular source electrodes 22a serving as first main electrodes are provided in their respective positions that correspond to the p-type base layers 12a and n⁺-type source layers 13a. A gate electrode 24d serving as a control electrode is formed on the area excluding the source electrodes 22a with a gate insulation film 23d interposed therebetween.

Substantially the same advantages as those of the MOSFET shown in FIG. 1 can be obtained from the MOSFET shown in FIG. 16. Since, furthermore, an electric field is eased at a corner of each of the p-type base layers 12a, a withstanding voltage can be prevented from decreasing.

For example, an interval Wp between adjacent gate-underlying p-type layers 14a is made smaller than an interval Wj between adjacent p-type base layers 12a, as shown in FIG. 16. This is eventually equal to the decrease in the area of the p-type base layers 12a. Thus, an electric field generated at a junction between each p-type base layer 12a and each low resistance layer 11a is eased. It is thus possible to prevent a withstanding voltage from decreasing. Such an advantage can be obtained from the structure shown in FIG. 15 in which the p-type base layers 12 are each shaped like a strip.

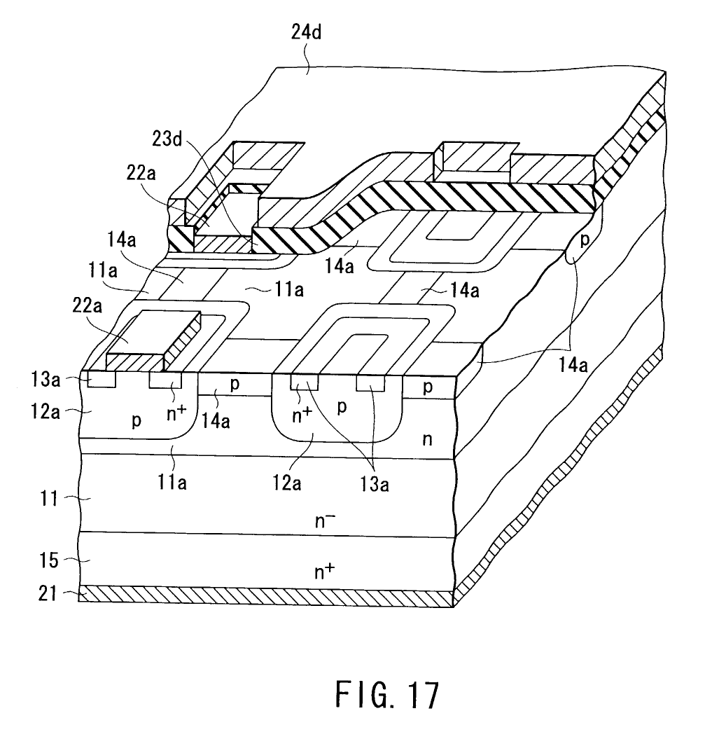

FIG. 17 shows another example of the structure of the power MOSFET according to the sixth embodiment. In this example, the arrangement of gate-underlying p-type layers 14a and n-type low resistance layers 11a is opposite to that in the structure of the power MOSFET shown in FIG. 16.

Referring to FIG. 17, a plurality of p-type base layers 12a serving as second semiconductor layers are arranged in a latticed manner (or staggered manner) in a surface area of an n-type low resistance layer 11a. A plurality of gate-underlying p-type layers 14a serving as fifth semiconductor layers are each formed like a rectangle between adjacent two p-type base layers 12a.

Substantially the same advantages as those of the MOSFET shown in FIG. 16 can be obtained even from the structure shown in FIG. 17.

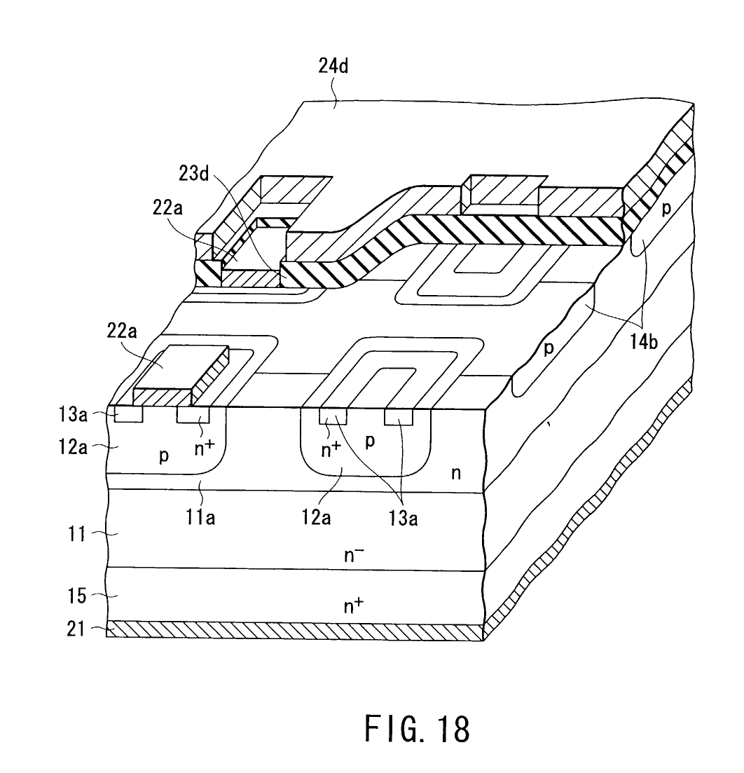

FIG. 18 shows still another example of the structure of the power MOSFET according to the sixth embodiment. In this example, a gate-underlying p-type layers are each shaped like a strip.

Referring to FIG. 18, a plurality of p-type base layers 12a serving as second semiconductor layers are arranged in a latticed manner (or staggered manner) in a surface area of an n-type low resistance layer 11a. A plurality of gate-underlying p-type layers 14a serving as fifth semiconductor layers are each formed like a strip between adjacent p-type base layers 12a.

Substantially the same advantages as those of the MOSFET shown in FIG. 16 can be obtained even from the structure shown in FIG. 18.

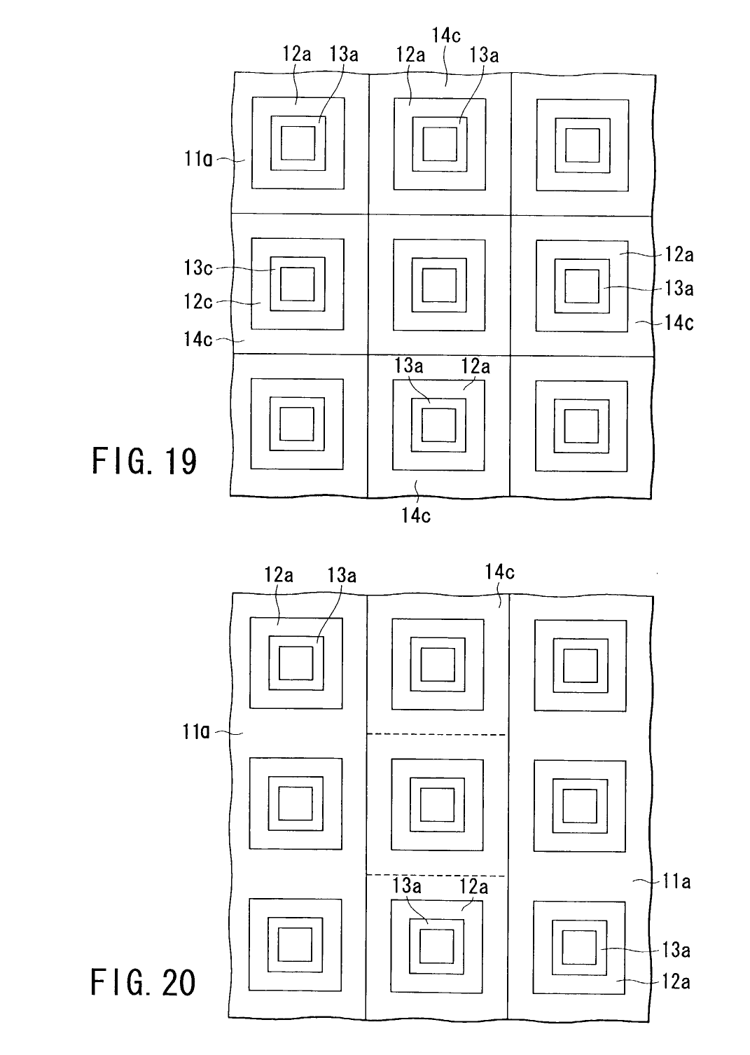

FIGS. 19 to 21 each show an example of layout of gate-underlying p-type layers in the power MOSFET according to the sixth embodiment.

FIG. 19 shows an example of the layout of gate-underlying p-type layers when p-type base layers are arranged in a latticed manner (or staggered manner). In this example, a plurality of gate-underlying p-type layers 14c serving as fifth semiconductor layers are arranged in a staggered manner so as to surround some of p-type base layers 12a serving as second semiconductor layers.

FIG. 20 shows another example of the layout of gate-underlying p-type layers when p-type base layers are arranged in a latticed manner (or staggered manner). In this example, a plurality of gate-underlying p-type layers 14c serving as fifth semiconductor layers are arranged in one direction and each shaped like a strip so as to surround some of p-type base layers 12a serving as second semiconductor layers.

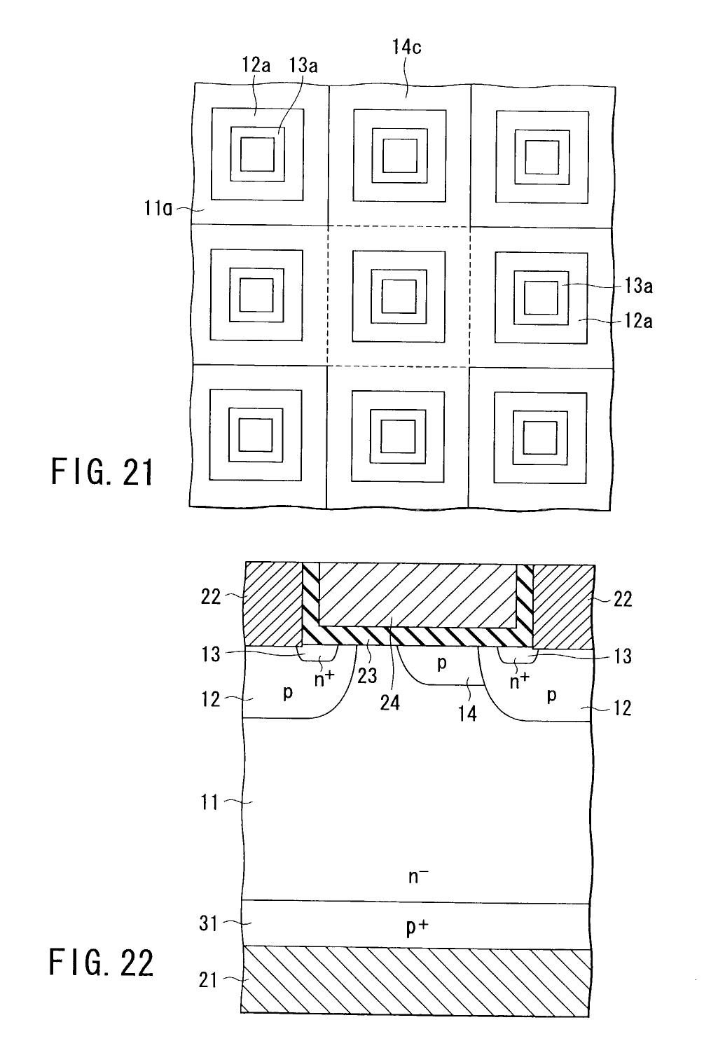

FIG. 21 shows still another example of the layout of gate-underlying p-type layers when p-type base layers are arranged in a latticed manner (or staggered manner). In this example, a plurality of gate-underlying p-type layers 14c serving as fifth semiconductor layers are arranged in two directions and each shaped like a strip so as to surround some of p-type base layers 12a serving as second semiconductor layers.

The MOSFET according to the sixth embodiment can easily be achieved with the structures shown in FIGS. 19 to 21.

(Seventh Embodiment)

FIG. 22 shows an example of an IGBT according to a seventh embodiment of the present invention. In FIG. 22, the same components as those of the MOSFET shown in FIG. 1 are denoted by the same reference numerals and their detailed descriptions are omitted. Only the components different from those in FIG. 1 will be described. The formation of an n-type low resistance layer is omitted from FIG. 22.

The IGBT (having a non-punch-through structure) shown in FIG. 22 has substantially the same structure as that of the MOSFET shown in FIG. 5 in which no n-type low resistance layer is formed. A plurality of p-type base layers 12 serving as second semiconductor layers are selectively formed by diffusion on one surface (top) of an n⁻-type drift layer 11 serving as a first semiconductor layer. Each of the p-type base layers 12 is formed like a strip in a first direction that is perpendicular to the plan of FIG. 22. At least one n⁺-type source layer 13 serving as a third semiconductor layer is selectively formed by diffusion in a surface area of each of the p-type base layers 12.

A p-type layer 14 serving as a fifth semiconductor layer is selectively formed in a surface area of the n⁻-type drift layer 11 between adjacent two p-type base layers 12. In the seventh embodiment, the p-type layer 14 is formed like a strip in the first direction along the p-type base layers 12. The p-type layer 14 is connected to one of the two p-type base layers 12 and has impurity concentration that is lower than that of the layers 12.

A p⁺-type drain layer 31 serving as a fourth semiconductor layer is formed on the other surface (bottom) of the n⁻-type drift layer 11. A drain electrode 21 serving as a second main electrode contacts the entire surface of the p⁺-type drain layer 31.

A source electrode 22, which includes part of the n⁺-type source layers 13, is formed as a first main electrode on each of the p-type base layers 12. The source electrodes 22 are each formed like a strip in the first direction. A planar gate electrode 24 is formed as a control electrode through a gate insulation film 23 between source electrodes 22. In other words, the gate electrode 24 is formed within a region extending from the n⁺-type source layers 13 in one p-type base layer 12 to the n⁺-type source layers 13 in another p-type base layer 12 via the n⁻-type drift layer 11a and p-type layer 14. The gate insulation film 23 has a thickness of about 0.1 μm.

An n⁺-type drain layer 15 in the MOSFET is formed of a p⁺-type drain layer 31. Thus, the MOSFET operates as an IGBT.

If the present invention is a MOS gate element, the switching characteristic is determined almost uniquely by the capacitance that depends upon the MOS gate structure. The MOS gate structure according to the seventh embodiment is effective in the IGBT.

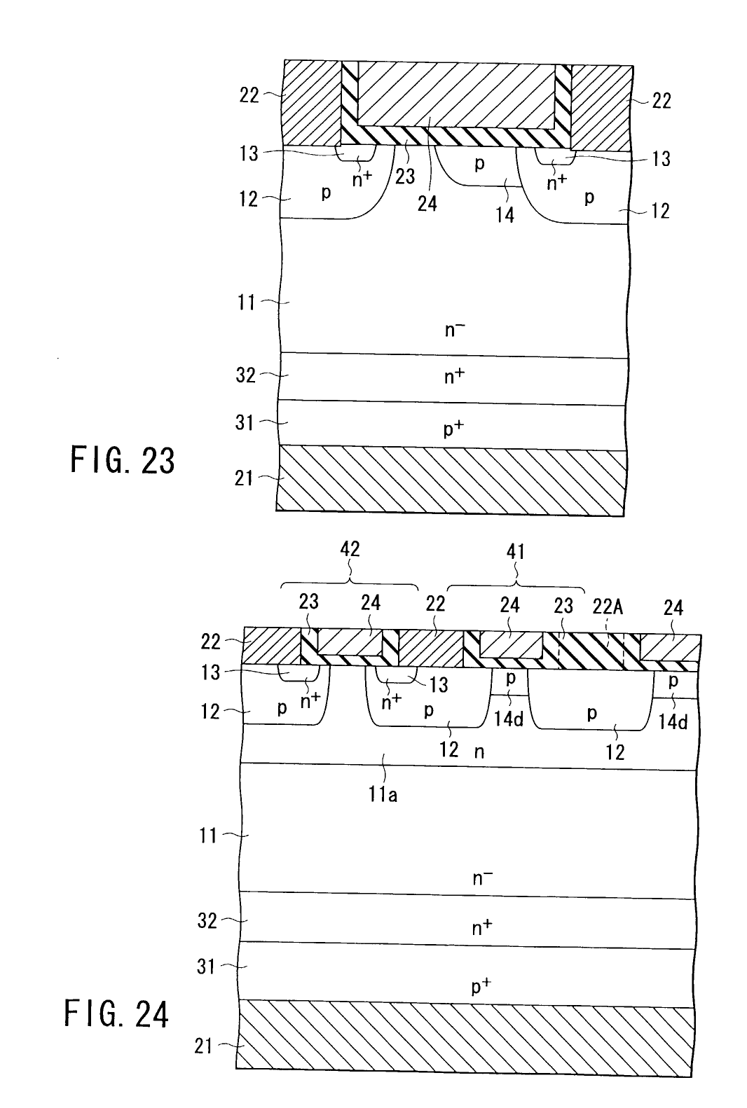

The IGBT is not limited to a non punch-through type but can be applied to a punch-through type as illustrated in FIG. 23. The punch-through type IGBT includes an n⁺-type buffer layer 32 serving as a sixth semiconductor layer between the n⁻-type drift layer 11 and p⁺-type drain layer 31.

FIG. 24 shows another example of the structure of the IGBT according to the seventh embodiment. In FIG. 24, the same components as those of the MOSFET shown in FIG. 23 are denoted by the same reference numerals and their detailed descriptions are omitted. Only the components different from those in FIG. 23 will be described. The IGBT shown in FIG. 24 includes an n-type low resistance layer. The IGBT is of a punch-through type.

Some IGBTs include a dummy cell (second cell) 41 in which part of a source contact (source electrode 22A) is not formed, as illustrated in FIG. 24. The conductivity of the n⁻-type drift layer 11 can greatly be varied if no source contact is formed.

In the dummy cell 41 of the IGBT so configured, a gate-underlying p-type layer 14d is formed as a fifth semiconductor layer. The p-type layer 14d completely covers the surface area of the n-type low resistance layer 11a. On the other hand, no gate-underlying p-type layer is formed in a normal cell (first cell) having a source contact (source electrode 22) on either side. When a low drain voltage is applied, the gate-to-drain capacitance decreases to increase switching speed. When a high drain voltage is applied, the gate-to-drain capacitance increases to reduce switching noise.

The seventh embodiment is not limited to an IGBT having a planar type MOS gate structure as shown in FIGS. 22 to 24 but can be applied to an IGBT having a trench type MOS gate structure.

(Eighth Embodiment)

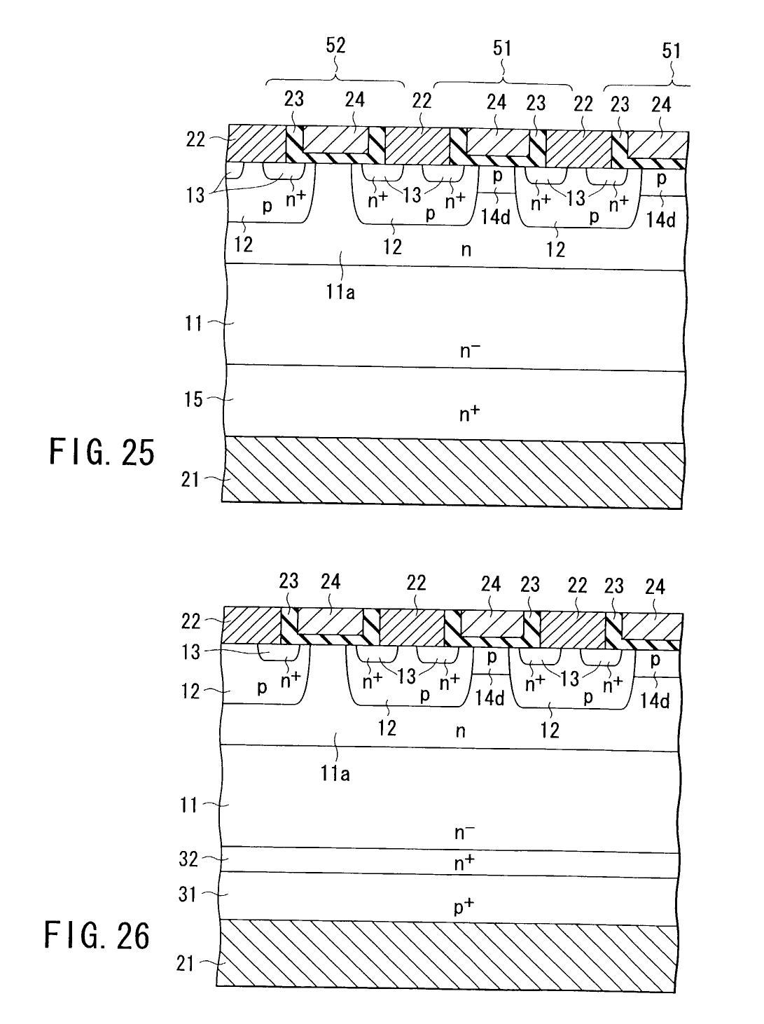

FIG. 25 shows an example of a structure of a power MOSFET according to an eighth embodiment of the present invention. In FIG. 25, the same components as those of the IGBT shown in FIG. 24 are denoted by the same reference numerals and their detailed descriptions are omitted. Only the components different from those in FIG. 24 will be described. The MOSFET shown in FIG. 25 includes an n-type low resistance layer.

As shown in FIG. 25, the MOSFET has a cell structure in which MOS cells (second cells) 51 each including a gate-underlying p-type layer 14d as a fifth semiconductor layer and MOS cells (first cells) 52 including no gate-underlying p-type layer are mixed. The gate-underlying p-type layer 14d is formed so as to completely cover the surface area of an n-type low resistance layer 11a.

The density (number) of the MOS cells (second cells) 51 is varied. It is thus possible to obtain the same advantages as those of the MOSFET in which the area ratio of the gate-underlying p-type layer 14d is varied. The ratio of the number of cells 51 to the total number of cells 51 and 52 in the entire device corresponds to the ratio of the gate-underlying p-type layer 14 shown in FIG. 7.

The manufacturing process of the MOSFET shown in FIG. 25 is simpler than that of the IGBT (shown in FIG. 24) in which no source contact is formed; therefore, it is advantageous in manufacturing.

Assume that a gate electrode 24 of the MOS cell 52 including no gate-underlying p-type layer has a split gate structure and a gate electrode 24 of the MOS cell 51 including a gate-underlying p-type layer 14d has a normal structure. When a low voltage is applied, the capacitance of the MOS cell 52 depends upon the area of the gate electrode 24 of the MOS cell 52 and thus the gate-to-drain capacitance decreases and the switching speed increases. On the other hand, when a high voltage is applied, the area of the gate electrode 24 of the MOS cell 51 increases and low-noise switching can be achieved.

The gate-underlying p-type layer 14d need not always be formed so as to completely cover the surface area of the n-type low resistance layer 11a. Even though the p-type layer 14d partly covers the surface area of the layer 11a, the same advantages can be obtained. In this case, too, it is important to design a device based on the ratio of the gate area of the entire device to the area of the gate-underlying layer (e.g., the surface area of the n-type low resistance layer 11a). It is desirable that a net dose have a value as shown in FIG. 8.

The eighth embodiment is not limited to the MOSFET but can be applied to an IGBT having a punch-through structure (or an IGBT having a non-punch-through structure, not shown) as shown in FIG. 26.

(Ninth Embodiment)

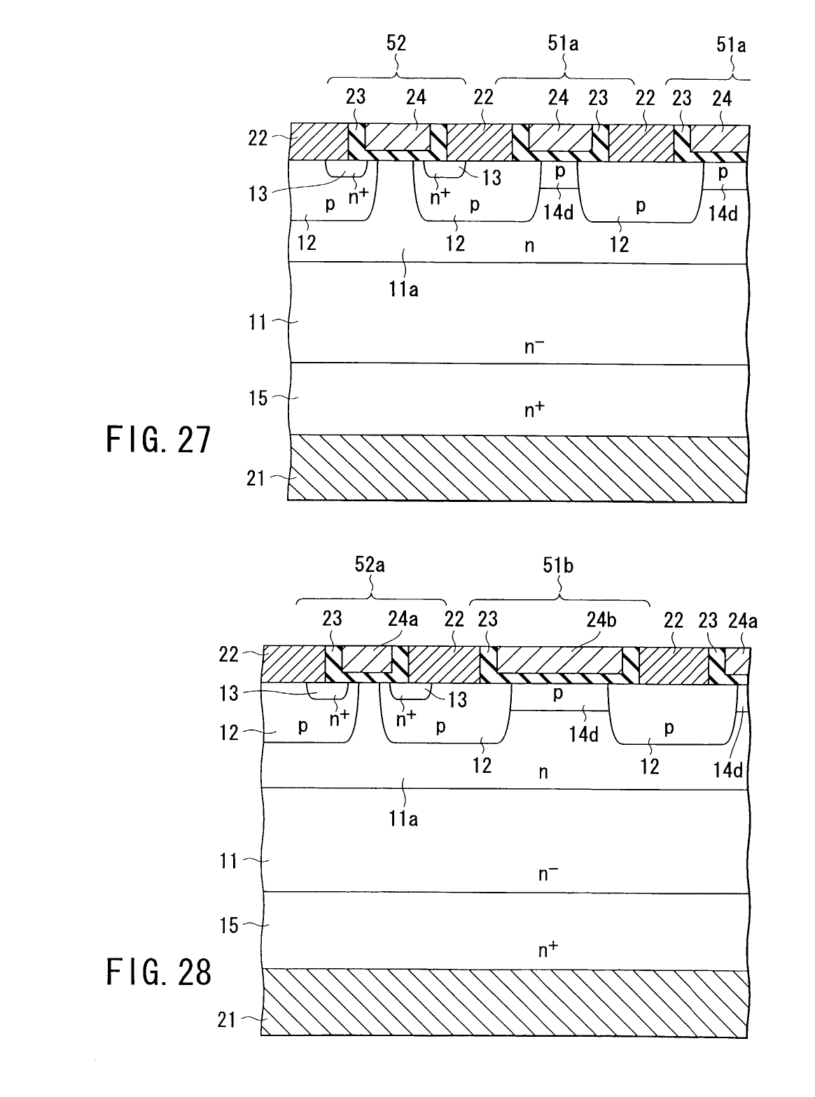

FIG. 27 shows a structure of a power MOSFET according to a ninth embodiment of the present invention. In FIG. 27, the same components as those of the MOSFET shown in FIG. 25 are denoted by the same reference numerals and their detailed descriptions are omitted. Only the components different from those in FIG. 25 will be described.

The MOSFET shown in FIG. 27 comprises MOS cells (first cells) 51a each having a gate-underlying p-type layer 14d as a fifth semiconductor layer. None of the MOS cells 51a include an n⁺-type source layer 13 serving as a third semiconductor layer.

The MOSFET so configured allows a breakdown voltage to increase. Even though a voltage is applied to a gate electrode 24, the MOS cells 51a do not operate because they do not have a path over which electrons flow. In other words, the MOS cells 51a only serve to increase gate-to-drain capacitance when a high drain voltage is applied. The MOS cells 51a do not therefore exert an influence upon on-resistance even though they do not have an n⁺-type source layer.

The MOS cells 51a have no parasitic bipolar transistors because they have no n⁺-type source layers. Even though an avalanche breakdown occurs when a high voltage is applied, holes generated can quickly be discharged. Thus, high-speed, low-noise switching characteristics can be achieved and avalanche tolerance can be improved.

In the MOSFET shown in FIG. 27, the gate length of the MOS cell 52 and that of the MOS cell 51a are equal to each other. In contrast, as shown in FIG. 28, a gate electrode 24b of the MOS cell 51b is lengthened and a gate electrode 24a of the MOS cell 52a is shortened. The advantage of high-speed and low-noise switching is therefore enhanced. In other words, only the gate capacitance of the MOS cell 52a corresponds to that of the entire device when a low voltage is applied. High-speed switching can be achieved by shortening the gate length of the MOS cell 52a. The gate-underlying p-type layer 14d is depleted when a high voltage is applied. The gate capacitance of the MOS cell 51b is therefore added to that of the MOS cell 52a. If the gate length of the MOS cell 51b is increased, the amount by which the gate capacitance increases can be increased, with the result that switching noise can greatly be reduced.

In the foregoing embodiments, the first conductivity type is an n type and the second conductivity type is a p type. However, the present invention is not limited to this. In each of the embodiments, the first conductivity type can be an n type and the second conductivity type can be a p type.

In the foregoing embodiments, silicon is used. The present invention is not limited to the use of silicon but can be applied to a device using silicon carbide (SiC), gallium nitride (GaN), a compound semiconductor such as aluminum nitride (AIN), and diamond.

In the foregoing embodiments, the present invention is applied to a MOSFET having a super-junction structure and a vertical switching element. However, it is not limited to this. For example, it can be applied to a horizontal MOSFET, IGBT, etc. if they are MOS or MIS gate elements.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An insulated gate semiconductor device comprising:
a first semiconductor layer of a first conductivity type;
a plurality of second semiconductor layers of a second conductivity type selectively formed in a surface area of the first semiconductor layer;
at least one third semiconductor layer of the first conductivity type formed in a surface area of each of the second semiconductor layers;
a plurality of first main electrodes connected to the second semiconductor layers and the third semiconductor layer, respectively;
a fourth semiconductor layer formed on a bottom of the first semiconductor layer;
a second main electrode connected to the fourth semiconductor layer;
a control electrode formed on a surface of each of the second semiconductor layers, the third semiconductor layer, and the first semiconductor layer with a gate insulation film interposed therebetween; and
at least one fifth semiconductor layer of the second conductivity type provided in the first semiconductor layer and connected to at least one of the plurality of second semiconductor layers, the fifth semiconductor layer having impurity concentration that is lower than that of the second semiconductor layers.

2. The insulated gate semiconductor device according to claim 1, wherein the fifth semiconductor layer is provided in the surface area of the first semiconductor layer and between the second semiconductor layers.

3. The insulated gate semiconductor device according to claim 2, wherein the second semiconductor layers are each formed like a strip and the fifth semiconductor layer is provided in a first direction along the second semiconductor layers.

4. The insulated gate semiconductor device according to claim 2, wherein the second semiconductor layers are each formed like a strip and the fifth semiconductor layer is provided in a second direction perpendicular to the first direction.

5. The insulated gate semiconductor device according to claim 1, wherein the fifth semiconductor layer is buried in the first semiconductor layer.

6. The insulated gate semiconductor device according to claim 1, wherein the control electrode has a planar structure.

7. The insulated gate semiconductor device according to claim 6, wherein the control electrode has a split gate structure.

8. The insulated gate semiconductor device according to claim 6, wherein the control electrode has a terrace gate structure.

9. The insulated gate semiconductor device according to claim 1, wherein the control electrode has a trench structure.

10. The insulated gate semiconductor device according to claim 1, wherein the control electrode has a trench structure and the fifth semiconductor layer is provided along a bottom of the control electrode and at least one side of the control electrode.

11. The insulated gate semiconductor device according to claim 1, wherein the second semiconductor layers are arranged in a latticed manner and the fifth semiconductor layer is formed like a rectangle between the second semiconductor layers.

12. The insulated gate semiconductor device according to claim 11, wherein the fifth semiconductor layer is provided between adjacent two second semiconductor layers of the second conductivity type.

13. The insulated gate semiconductor device according to claim 11, wherein the fifth semiconductor layer is provided between adjacent four second semiconductor layers of the second conductivity type.

14. The insulated gate semiconductor device according to claim 13, wherein an interval between adjacent fifth semiconductor layers of the second conductivity type is shorter than an interval between adjacent second semiconductor layers of the second conductivity type.

15. The insulated gate semiconductor device according to claim 1, wherein the second semiconductor layers are arranged in a latticed manner and the fifth semiconductor layer is formed like a strip between second semiconductor layers of the second conductivity type.

16. The insulated gate semiconductor device according to claim 1, wherein the second semiconductor layers are arranged in a latticed manner and the fifth semiconductor layer is formed so as to surround some of the second semiconductor layers of the second conductivity type.

17. The insulated gate semiconductor device according to claim 16, wherein the fifth semiconductor layers of the second conductivity type are arranged in a staggered manner.

18. The insulated gate semiconductor device according to claim 16, wherein the fifth semiconductor layers of the second conductivity type are arranged like a strip.

19. The insulated gate semiconductor device according to claim 18, wherein the fifth semiconductor layers of the second conductivity type are arranged in one direction.

20. The insulated gate semiconductor device according to claim 18, wherein the fifth semiconductor layers of the second conductivity type are arranged in two directions.

21. The insulated gate semiconductor device according to claim 1, wherein the fourth semiconductor layer is a semiconductor layer of the first conductivity type.

22. The insulated gate semiconductor device according to claim 1, wherein the fourth semiconductor layer is a semiconductor layer of the second conductivity type.

23. The insulated gate semiconductor device according to claim 22, further comprising a sixth semiconductor layer of the first conductivity type provided between the fourth semiconductor layer and the first semiconductor layer.

24. The insulated gate semiconductor device according to claim 1, wherein a surface area of the fifth semiconductor layer is 30% or more of a surface area of the first semiconductor layer between adjacent second semiconductor layers of the second conductivity type.

25. The insulated gate semiconductor device according to claim 1, wherein the fifth semiconductor layer has an effective impurity dose of 3.2×10¹² cm⁻² or smaller.

26. The insulated gate semiconductor device according to claim 1, wherein a ratio (Np/Lj) of an effective impurity dose (Np) of the fifth semiconductor layer to a distance (Lj) between adjacent second semiconductor layers of the second conductivity type is smaller than 2×10¹⁵ cm⁻³.

27. The insulated gate semiconductor device according to claim 1, wherein a ratio (Np/(Lj·Xj)) of an effective impurity dose (Np) of the fifth semiconductor layer to a product of a distance (Lj) between adjacent second semiconductor layers of the second conductivity type and a depth (Xj) of the second semiconductor layers is smaller than 5×10¹⁸ cm⁻⁴.

28. An insulated gate semiconductor device comprising:
a first semiconductor layer of a first conductivity type;
a plurality of second semiconductor layers of a second conductivity type selectively formed in a surface area of the first semiconductor layer;
at least one third semiconductor layer of the first conductivity type formed in a surface area of each of the second semiconductor layers;
a plurality of first main electrodes connected to the second semiconductor layers and the third semiconductor layer, respectively;
a fourth semiconductor layer formed on a bottom of the first semiconductor layer;
a second main electrode connected to the fourth semiconductor layer;
a control electrode formed on a surface of each of the second semiconductor layers, the third semiconductor layer, and the first semiconductor layer with a gate insulation film interposed therebetween; and
at least one fifth semiconductor layer of the second conductivity type provided in the first semiconductor layer and connected to at least one of the plurality of second semiconductor layers, the fifth semiconductor layer having impurity concentration that is lower than that of the second semiconductor layers,
wherein capacitance between the control electrode and the second main electrode decreases when a voltage applied to the second main electrode is low and the capacitance remains constant or increases when the voltage is high.

29. An insulated gate semiconductor device comprising:
a first semiconductor layer of a first conductivity type;
a plurality of second semiconductor layers of a second conductivity type selectively formed in a surface area of the first semiconductor layer;
at least one third semiconductor layer of the first conductivity type formed in a surface area of each of the second semiconductor layers;
a plurality of first main electrodes connected to the second semiconductor layers and the third semiconductor layer, respectively;
a fourth semiconductor layer formed on a bottom of the first semiconductor layer;
a second main electrode connected to the fourth semiconductor layer;
a control electrode formed on a surface of each of the second semiconductor layers, the third semiconductor layer, and the first semiconductor layer with a gate insulation film interposed therebetween; and
at least one fifth semiconductor layer of the second conductivity type provided in the first semiconductor layer and connected to at least one of the plurality of second semiconductor layers, the fifth semiconductor layer having impurity concentration that is lower than that of the second semiconductor layers,
wherein capacitance between the control electrode and the second main electrode starts to increase when a voltage applied to the second main electrode is one-third to two-thirds of a rated voltage.

30. An insulated gate semiconductor device comprising:
a first semiconductor layer of a first conductivity type;
a plurality of second semiconductor layers of a second conductivity type selectively formed in a surface area of the first semiconductor layer;
at least one third semiconductor layer of the first conductivity type formed in a surface area of each of the second semiconductor layers;
a plurality of first main electrodes connected to the second semiconductor layers and the third semiconductor layer, respectively;
a fourth semiconductor layer formed on a bottom of the first semiconductor layer;
a second main electrode connected to the fourth semiconductor layer;
a control electrode formed on a surface of each of the second semiconductor layers, the third semiconductor layer, and the first semiconductor layer with a gate insulation film interposed therebetween; and
at least one fifth semiconductor layer of the second conductivity type provided in the first semiconductor layer and connected to at least one of the plurality of second semiconductor layers, the fifth semiconductor layer having impurity concentration that is lower than that of the second semiconductor layers,
wherein the fifth semiconductor layer of the second conductivity type is completely depleted when a voltage applied to the second main electrode is one-third to two-thirds of a rated voltage.

31. An insulated gate semiconductor device comprising first and second cells each including a plurality of second semiconductor layers of a second conductivity type selectively formed in a surface area of a first semiconductor layer of a first conductivity type,
the first cell including at least one third semiconductor layer of the first conductivity type formed in a surface area of each of the second semiconductor layers and a plurality of first main electrodes connected to the second semiconductor layers and the third semiconductor layer, respectively and
the second cell including a fifth semiconductor layer of the second conductivity type provided between adjacent second semiconductor layers of the second conductivity type and having impurity concentration that is lower than that of the second semiconductor layers.

32. The insulated gate semiconductor device according to claim 31, wherein the fifth semiconductor layer of the second cell is provided so as to completely cover the surface area of the first semiconductor layer.

33. The insulated gate semiconductor device according to claim 31, wherein the second cell further includes a first main electrode connected to the second semiconductor layers of the second conductivity type or at least one third semiconductor layer of the first conductivity type formed in a surface area of each of the second semiconductor layers and a first main electrode connected to both the second semiconductor layers and the third semiconductor layer.

34. The insulated gate semiconductor device according to claim 31, wherein a length of a control electrode or an interval between adjacent second semiconductor layers in the second cell is greater than a length of a control electrode or an interval between adjacent second semiconductor layers in the first cell.
